(19) United States
(12) Patent Application Publication
(10) Pub. No.: US 2012/0001212 A1
(43) Pub. Date: Jan. 5, 2012

(54) Light-Emitting Diode Packaging Structure and Substrate Therefor

(75) Inventors: Shih-Long Wei, Hsinchu County (TW); Shen-Li Hsiao, Hsinchu County (TW); Chien-Min Shao, Hsinchu County (TW); Chien-Hung Ho, Hsinchu County (TW)

(73) Assignee: VIKING TECH CORPORATION, Hsinchu County (TW)

(21) Appl. No.: 12/859,845

(22) Filed: Aug. 20, 2010

(30) Foreign Application Priority Data
Jul. 5, 2010 (TW) 099212713

(51) Int. Cl. H01L 33/48

(52) U.S. Cl. 257/98; 257/E33.056

(57) ABSTRACT

A light-emitting diode (LED) packaging structure and a substrate for the packaging structure are provided. The light-emitting diode packaging structure includes a metal substrate having a first surface and a second surface opposite to the first surface, and the first surface has a concave portion with a sidewall and a bottom, allowing an anode film to be formed on the metal substrate; a plurality of electrically conductive pads formed on the bottom of the concave portion; an optical treatment layer formed on the sidewall of the concave portion; and an LED die mounted on the bottom of the concave portion and electrically connected to the electrically conductive pads. Desired electrical insulating property between any two adjacent electrically conductive pads can be obtained by the anode film formed on the metal substrate, while a good thermal conductivity of the metal substrate is maintained.

### FIELD OF THE INVENTION

The present invention relates to light-emitting structures, and more particularly to a light-emitting diode packaging structure.

### BACKGROUND OF THE INVENTION

Light emitting diode (LED) is subject to a kind of semiconductor devices. With the rapid development of the LED technology and the increasing maturity of the technologies of the related peripheral integrated circuit control elements and heat dissipating, LED applications become more diversified. Early development for applications of LED included low-power indicator lamps and light source for mobile phone keypads. Nowadays, LEDs are applied to the LED backlight, general household lighting, and even large-scale lighting products such as electronic billboards which are lower in utility consumption, longer in lifetime and higher in color rendering index.

Referring to FIG. 1, a conventional LED packaging structure 1 is illustrated for instance, which has a substrate 10 for carrying an LED 11 and an encapsulant 12 formed on the substrate 10 for encapsulating the LED 11. The encapsulant 12 is so formed that a plastic mold (not shown in the drawing) is used to be mounted on the substrate 10 for covering the LED 11, allowing encapsulating material for forming the encapsulant 12 to be filled thereinto and cured to thereby form the encapsulant 12. Desired optical performance through the encapsulant 12 can thus be obtained by the light emitted from the LED 11.

However, since the encapsulant 12 needs to be adhered to the substrate 10 and encapsulate the LED 11, a special mold or plastic frame is required to be used to form the desired encapsulant 12 by using an expensive press molding machine or injection molding machine. Accordingly, this results in longer molding time and higher molding cost. Further, LED 11 is vulnerable during the molding process for forming the encapsulant 12, thus making the yield of the final products lower than desired.

Furthermore, since the light source of the LED 11 is diffused by the encapsulant 12, light emission performance from the light source of the LED 11 can easily be affected by the material of the encapsulant 12.

Therefore, it is imperative to overcome the above drawbacks of the prior art.

### SUMMARY OF THE INVENTION

In light of the drawbacks of the aforementioned prior art, the present invention provides an LED packaging structure that can be manufactured at a lower cost, with a higher yield, and that can have an improved light emission performance.

According to the present invention, a substrate for an LED packing structure is provided. The substrate of the present invention comprises: a body having a first surface and a second surface opposing the first surface, wherein the first surface is formed with a concave portion having a sidewall and a bottom, and an anode film is formed on the body; and a plurality of electrically conductive pads formed on the bottom of the concave portion. The substrate for LED packaging structure may further comprise an optical treatment layer formed on the sidewall of the concave portion.

According to the above substrate, an LED packaging structure is further provided, which comprises: a metal substrate having a first surface and a second surface opposing the first surface, wherein the first surface is formed with a concave portion having a sidewall and a bottom, and an anode film is formed on the metal substrate; a plurality of electrically conductive pads formed on the bottom of the concave portion; and an LED die mounted on the bottom of the concave portion and electrically connected to the electrically conductive pads.

The LED packaging structure can further comprise an optical treatment layer formed on the sidewall of the concave portion.

In the above LED packaging structure, the sidewall of the concave portion is oblique or progressively enlarged upward from the bottom. In an embodiment, the bottom of the concave portion has a die bonding area for allowing the LED die to be mounted therein and the electrically conductive pads to be formed outside the die bonding area. In another embodiment, the die bonding area on the bottom of the concave portion can be selectively electrically connected with the electrically conductive pads in order to perform a flip chip packaging of a flip-chip LED. During the flip chip packaging process, the LED chip will be turned over for electrical connecting the LED chip with the substrate, so as to decrease the signal transmitting distance between the LED chip and the substrate. It is thus suitable for the packaging of a high-speed device. In addition, the size of the final products can be reduced.

Further, compared with a traditional hemispherical LED packaging structure, the shape of the concave portion is mainly used for the employment of a simple dispensing method for encapsulating the LED die, and the sidewall of the concave portion can be used for light reflection.

In the aforesaid LED packaging structure, the optical treatment layer can be a light reflection layer, and the LED die can be electrically connected to the electrically conductive pads through bonding wires.

The LED packaging structure further includes a circuit layer disposed on the second surface of the metal substrate and a plurality of conductive columns electrically connecting the electrically conductive pads and the circuit layer and penetrating the bottom of the concave portion and the second surface of the metal substrate.

Consequently, in the LED packaging structure of the present invention, the metal substrate having good thermal conductivity is used as a carrier. The anode film can be an insulating layer between the LED die and the metal substrate. The electrically conductive pads and the conductive columns are together formed into an electrical connecting path. Thus, the metal substrate may provide not only thermal conductivity, but also electrical insulation. Moreover, the metal substrate has the concave portion thereon, such that the LED packaging process can be accomplished by applying a dispensing method which is simple in process and economic in equipment. The LED die performs an optical function through the concave portion such that the influence of the material of the formed encapsulant in the prior art can be resolved. The light emission performance of the LED packaging structure of the present invention can be improved.

### BRIEF DESCRIPTION OF THE DRAWINGS

FIG. 1 is a cross-sectional view of a conventional LED packaging structure.

FIG. 2 is a cross-sectional view of a LED packaging structure according to the present invention.

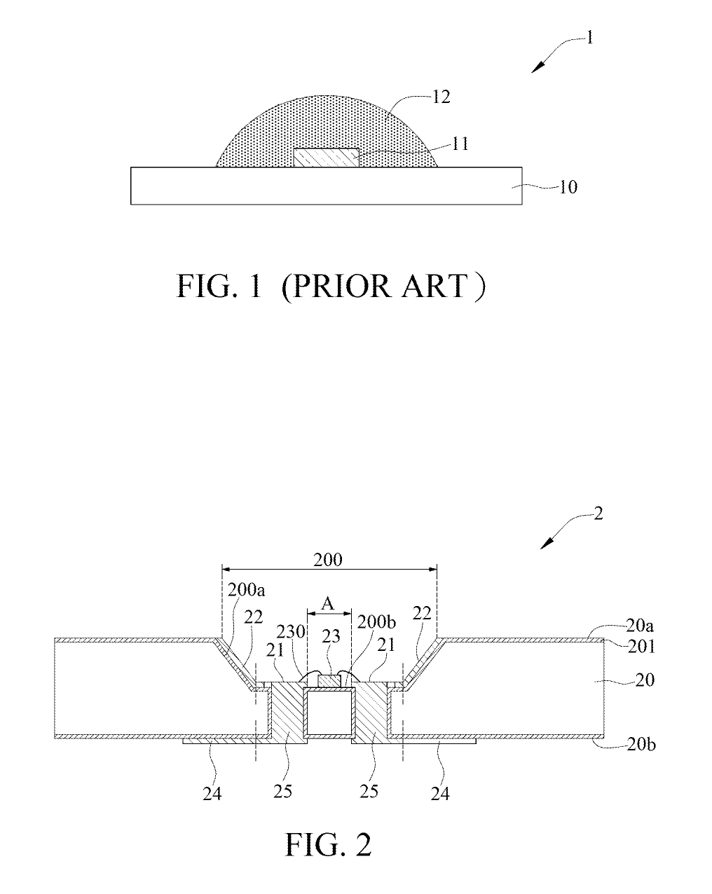

### DETAILED DESCRIPTION OF THE PREFERRED EMBODIMENTS

The following specific embodiment is provided to illustrate the present invention. Others skilled in the art can readily gain an insight into other advantages and features of the present invention based on the contents disclosed in this specification. The present invention can also be performed or applied in accordance with other different embodiments. Various modifications and changes based on different viewpoints and applications yet still within the scope of the present invention can be made in the details of the specification.

Referring to FIG. 2, an LED packaging structure 2 according to the present invention is illustrated. The LED packaging structure 2 has a metal substrate 20 having a first surface 20a and a second surface 20b opposite to the first surface 20a, a plurality of electrically conductive pads 21 and an LED die 23. The first surface 20a of the metal substrate 20 is formed with a concave portion 200 having a sidewall 200a and a bottom 200b. And, an anode film 201 is formed on the metal substrate 20 (including the first surface 20a, the second surface 20b, the sidewall 200a and the bottom surface 200b of the concave portion 200 and the inner surface of a through hole described hereafter). If the metal substrate 20 of the LED packaging structure 2 is made of aluminum, the anode film 201 on the metal substrate 20 can be made of alumina oxide.

Furthermore, the sidewall 200a of the concave portion 200 is oblique and the concave portion 200 is progressively enlarged upward from the bottom 200b which has a die bonding area A.

The electrically conductive pads 21 are formed on the bottom 200b of the concave portion 200 and located outside the die bonding area A. In an embodiment of the employment of a flip-chip packaging, the die bonding area A also can be selectively electrically connected with the electrically conductive pads 21.

If necessary, the metal substrate 20 may further include an optical treatment portion 22 such as a reflection layer which may be made of silver, formed on the sidewall 200a of the concave portion 200.

The LED die 23 is mounted on the die bonding area A of the bottom 200b of the concave portion 200 and electrically connected to the electrically conductive pads 21 by bonding wires 230.

Moreover, the LED packaging structure 2 further includes a circuit layer 24 formed on the second surface 20b of the metal substrate 20, and a plurality of conductive columns 25 penetrating the bottom 200b of the concave portion 200 and the second surface 20b of the metal substrate 20; the conductive columns 25 electrically connect the electrically conductive pads 21 and the circuit layer 24. The aforesaid electrically conductive pads 21, the circuit layer 24 and the conductive columns 25 are formed by forming a through hole penetrating the metal substrate 20 by laser or etching; forming the anode film 201 on the metal substrate 20 and the inner surface of the through hole by anodic treatment; forming the electrically conductive pads 21 and the optical treatment portion 22 on the first surface 20a of the metal substrate 20 by conventional thick film printing technology or thin film technology such as sputtering, lithography, electroplating and chemical deposition; forming the conductive columns 25 in the through hole; and forming the circuit layer 24 on the second surface 20b. Subsequently, the substrate for LED packaging structure can be obtained according to the present invention.

Furthermore, since the metal substrate 20 has the concave portion 200 thereon, the LED packaging process can be accomplished by applying a dispensing method which is simple in process and economic in equipment. The LED die 23 performs an optical function through the concave portion 200 such that the influence of the material of the formed encapsulant in the prior art can be eliminated in the subsequent process. Therefore, the light emission performance of the LED packaging structure of the present invention can be effectively improved.

The foregoing descriptions of the detailed embodiments are only to disclose the features and functions of the present invention and do not intend to limit the scope of the present invention. It should be understood to those in the art that all modifications and variations according to the spirit and principle of the present invention should fall within the scope of the appended claims.

What is claimed is:

1. A light-emitting diode (LED) packaging structure, comprising:
a metal substrate having a first surface and an opposing second surface, wherein the first surface is formed with a concave portion having a sidewall and a bottom, and an anode film is formed on the metal substrate;
a plurality of electrically conductive pads formed on the bottom of the concave portion; and
an LED die mounted on the bottom of the concave portion and electrically connected to the electrically conductive pads.

2. The light-emitting diode packaging structure of claim 1, wherein the sidewall of the concave portion is oblique.

3. The light-emitting diode packaging structure of claim 1, wherein the concave portion is progressively enlarged upward from the bottom thereof.

4. The light-emitting diode packaging structure of claim 1, wherein the bottom of the concave portion has a die bonding area for the LED die to be mounted thereon and the electrically conductive pads are formed on the bottom outside the die bonding area.

5. The light-emitting diode packaging structure of claim 1, further comprising an optical treatment layer formed on the sidewall of the concave portion.

6. The light-emitting diode packaging structure of claim 5, wherein the optical treatment layer is an optical reflection layer.

7. The light-emitting diode packaging structure of claim 1, wherein the LED die is electrically connected to the electrically conductive pads by bonding wires.

8. The light-emitting diode packaging structure of claim 1, further comprising a circuit layer disposed on the second surface of the metal substrate and a plurality of conductive columns penetrating through the bottom of the concave portion and the second surface of the metal substrate

9. The light-emitting diode packaging structure of claim 8, wherein the conductive columns electrically connect the electrically conductive pads and the circuit layer.

10. A substrate for light-emitting diode packaging structure, comprising:
a body having a first surface and an opposing second surface, wherein the first surface is formed with a concave portion having a sidewall and a bottom, and an anode film is formed on the body; and
a plurality of electrically conductive pads formed on the bottom surface of the concave portion.

11. The substrate of claim 10, wherein the sidewall of the concave portion is oblique.

12. The substrate of claim 10, wherein the concave portion is progressively enlarged upward from the bottom thereof.

13. The substrate of claim 10, further comprising an optical treatment layer formed on the sidewall of the concave portion.

14. The substrate of claim 13, wherein the optical treatment layer is an optical reflection layer.

15. The substrate of claim 10, further comprising a circuit layer disposed on the second surface of the body and a plurality of conductive columns penetrating the bottom of the concave portion and the second surface of the body.

16. The substrate of claim 15, wherein the conductive columns electrically connect the electrically connective pads and the circuit layer.
